(19) United States
(12) Patent Application Publication
(10) Pub. No.: US 2004/0085059 A1
(43) Pub. Date: May 6, 2004

(54) METHOD AND APPARATUS TO PROVIDE ACCURATE HIGH SPEED WIDE RANGE CURRENT MEASUREMENT IN AUTOMATED TESTING EQUIPMENT

(76) Inventor: Edward E. Smith, San Jose, CA (US)

Correspondence Address: NGUYEN & ASSOCIATES, 16168 BLOSSOM HILL ROAD, LOS GATES, CA, 95032, US

(21) Appl. No.: 10/285,184

(22) Filed: Oct. 31, 2002

(51) Int. Cl. G01R 1/00

(52) U.S. Cl. 324/158.1

(57) ABSTRACT

A current measurement circuit utilizing pn junction diodes is presented. The inherent non-linear current-to-voltage (I-V) characteristics of diodes allow a wide dynamic current range to be accommodated. By periodically calibrating the diode-based current measurement circuit and storing the associated parametric I-V data points in a look-up table, the value of a current can be made available quickly by looking up a voltage value in the look-up table or by interpolating between two known data points as required. The effects induced by the temperature variations on diodes due to self-heating, environmental, and others, are automatically taken into account because parametric I-V data points are acquired and stored in the look-up table as a result of periodic calibration sessions which take place frequently enough so that any effects due to temperature changes are accounted for and reflected in the stored I-V data points. In so doing, a current with the temperature variation effects factored in can be accurately and automatically determined by measuring the voltage provided to the diodes, using it to look up a stored current data point that correspond to the measured voltage. A computer processor executing the instructions stored in memory automatically carries out such look up and interpolation process. Accordingly, unlike the traditional approach, there is no RC settling time with which to contend and multiple resistor network switching steps can be avoided.

### CROSS-REFERENCE TO RELATED APPLICATION

This application is related to United States provisional patent application Serial No. ______, filed ______ by Edward Smith, Attorney Docket No. 3MTS-003, entitled “FLOATING DC POWER SOURCE CIRCUIT” which is to be commonly assigned to Third Millennium Test Solutions Corporation of San Jose, Calif. The disclosure of which is hereby incorporated by reference, verbatim and with the same effect as though it were fully and completely set forth herein.

### FIELD OF THE INVENTION

The invention relates generally to Automated Test Equipments (ATEs), and more particularly to current measurement circuits of ATEs.

### BACKGROUND OF THE INVENTION

To provide quality assurance, semiconductor device makers systematically perform tests on their products to ensure that they meet or exceed all of their design parameters. Some of the types of tests routinely performed include device parametric testing (a.k.a. DC testing), device logic function testing, and device timing testing (a.k.a. AC testing). The semiconductor device being tested is commonly known as the Device Under Test (DUT) and the test system used in conducting the above tests on the DUT is commonly known as Automatic Test Equipment (ATE).

In carrying out the aforementioned tests on very sensitive DUTs, the ATE is necessarily very precise and, for DC measurements, must function over wide dynamic ranges of voltages and currents. The wide dynamic ranges of voltages and currents are required to accommodate all the states and ports of semiconductor devices. In addition, to improve test throughput and maximize test capacity at minimum total cost, it is desirable that the ATE makes measurements as rapidly as possible while conforming to a wide range of sensitivity, resolution, and accuracy requirements. These are difficult tasks considering that measurement time generally increases as requirements for sensitivity, resolution, accuracy, and the range of current measurements increase.

In terms of DUT current measurements, many DUT tests require that a current flowing through a particular port be measured under some specific applied voltage conditions. The current is not directly measured. Rather, the current flowing through the ports of the DUT is indirectly measured as a voltage drop across precision resistors with known values from which the current can then be calculated. The traditional current measurement approach of using precision resistors has its limitations in accommodating a wide range of current measurements as well as in reducing settling time. Under the traditional approach, different resistors are used to accommodate a wide range of currents. This typically involves removing and replacing (using relays) an installed resistor in the current measurement circuit with a different resistor with a different value to accommodate a different current value. Such resistor removal and replacement significantly increase measurement time especially when the number of current measurements and current measurement tests are high (e.g., in the millions during a production test day).

Moreover, a relatively large capacitor is typically used in stabilizing the voltage measurements in determining the current across the resistor. However, such capacitor use introduces an RC time constant that directly impacts the current measurement circuit settling time. This impact is exacerbated in measuring small currents. To measure a small current, a relatively large resistor is typically needed under the traditional approach. To speed up the charging of a capacitor thereby reducing the settling time, however, a small resistor must be used initially so as to produce a large current. Once the capacitor is charged to produce the required minimum voltage, the small resistor must then be removed and replaced by the larger resistor. Because of the resistor removal and replacement process, such an approach to reduce settling time is not overly effective.

Thus, a need exists for an ATE current measurement methodology and apparatus that minimize the overall current measurement time over a wide dynamic current range while still achieving the required sensitivities, accuracies, and resolutions.

### SUMMARY OF THE INVENTION

Accordingly, the present invention provides an ATE current measurement methodology and apparatus that minimize the overall current measurement time over a wide dynamic current range while still achieving the required sensitivities, accuracies, and resolutions.

The present invention meets the above objectives with a current measurement circuit that resides in the Pin Electronics (PE) circuit of an ATE system. The ATE system is a typical ATE system having a central processing unit (CPU), Input/Output (I/O) peripherals connected to the CPU, at least one data storage device coupled to the CPU, and a test head electrically linked to the CPU in which the PE circuit is located.

The current measurement circuit comprises a first voltage follower circuit and a diode cluster circuit coupled to the voltage follower circuit. The first voltage follower circuit receives a predetermined voltage at a non-inverted input and ensures that any losses caused by the diode cluster circuit and the resistor are compensated. The diode cluster circuit provides a current at its output in response to a voltage applied across the diode that results from the predetermined voltage provided as an input to the first voltage follower circuit. The current measurement circuit is designed to operate together with the CPU executing stored instructions to measure the current associated with the predetermined input voltage.

In accordance with the present invention, the data storage device stores the instructions and current-voltage (I-V) characteristics data points measured at the diode cluster circuit during calibration sessions using predetermined input voltages and predetermined resistance connected to the diode cluster circuit. Using the measured voltage across the diode cluster circuit, the associated current can be computed by dividing the measured voltage across the diode cluster circuit by the known resistance value. The I-V characteristics data points stored in the data storage device are updated periodically but at a frequency that ensures that effects by temperatures on the diode cluster circuit are accounted for in the stored I-V data points. The calibration frequency may be varried to counter increasing effects due to temperature changes. During production current measurement, the stored instructions perform the following steps: 1) determining the voltage across the diode cluster circuit; 2) using the voltage taken across the diode cluster circuit as an index, determining a corresponding current value from the I-V characteristics data points stored; and 3) outputing the corresponding current value as the measured current. The determining the corresponding current value step may require an interpolaton using two voltage data points that are closest in value to the voltage taken across the diode cluster diode.

In one embodiment, the current measurement circuit further comprises a second voltage follower circuit connected to the diode cluster circuit and the inverted input of the first voltage follower circuit. The second voltage follower circuit serves as a buffer to prevent excessive current from being drawn. In one embodiment, the diode cluster circuit comprises a first diode set having a plurality of pn junction diodes connected together in parallel and a second diode set having a plurality of pn junction diodes connected together in parallel. The input of the first diode set is connected to the output of the second diode set and the output of the first diode set is connected to the input of the second diode set to form a loop to accommodate input voltages of both polarity.

All the features and advantages of the present invention will become apparent from the following detailed description of its preferred embodiment whose description should be taken in conjunction with the accompanying drawings wherein like reference numerals refer to like parts throughout.

### BRIEF DESCRIPTION OF THE DRAWINGS

FIG. 1 illustrates a block diagram of ATE 100 that implements the present invention.

FIG. 2 illustrates, as examples, I-V curves of a typical pn junction diode at different temperatures T1-T3.

FIG. 3 illustrates an embodiment of current measurement circuit 300 in accordance with the present invention.

FIG. 4 illustrates an exemplary flow chart of the instructions stored in a data storage device of computer system 102 which when executed by the CPU determines the current associated with measured didode voltage V_{D}.

FIG. 5 illustrates, as an example, a flow chart of the interpolation steps associated with step 420 of FIG. 4.

FIG. 6 illustrates the geometrical relationship between the parameters used in interpolation equation (2).

### DETAILED DESCRIPTION OF THE INVENTION

In the following detailed description of the present invention, numerous specific details are set forth in order to provide a thorough understanding of the present invention. However, it will be obvious to one skilled in the art that the present invention may be practiced without these specific details. In other instances well known methods, procedures, components, and circuits have not been described in detail as not to unnecessarily obscure aspects of the present invention. Furthermore, while the following detailed description of the present invention describes its application primarily in Automatic Test Equipment (ATE), it is to be appreciated that the present invention can be used in any apparatus or system requiring a current measurement circuit.

In accordance with the present invention, a current measurement circuit utilizes pn junction diodes in measuring currents. The inherent non-linear current-to-voltage (I-V) characteristics of diodes allow a wide dynamic current range to be accommodated. More particularly, the logarithmic current-to-voltage characteristics of diodes allow currents to be represented in terms of logarithmic decades thereby greatly increasing the current measurement range without having to remove and replace resistors as in the traditional approach thereby saving precious time. By periodically calibrating the diode-based current measurement circuit and storing the associated parametric I-V data points in a look-up table, the value of a current can be made available quickly by looking up a voltage value in the look-up table or by interpolating between two known data points as required. The effects induced by the temperature variations on diodes due to self-heating, environmental, and others, are automatically taken into account because parametric I-V data points are acquired and stored in the look-up table as a result of periodic calibration sessions which take place frequently enough so that any effects due to temperature changes are accounted for and reflected in the stored I-V data points. In so doing, a current with the temperature variation effects factored in can be accurately and automatically determined by measuring the voltage provided to the diode, using it to look up a stored current data point that correspond to the measured voltage. If there is no exact match, an interpolated value may be determined using the current data point correspond to two voltage data points that are closest in value to the measured voltage. Such look-up and interpolation process is automatically carried out by a computer processor executing the programmed steps stored in memory (e.g., data storage device). Accordingly, unlike the traditional approach, there is no RC settling time with which to contend and multiple resistor network switching steps can be avoided. Current measurements can therefore be measured more quickly. Furthermore, by controlling the mass of the diodes (e.g., using a cluster of diodes arranged in parallel or in series), the effects caused by thermal changes can be further controlled and reduced.

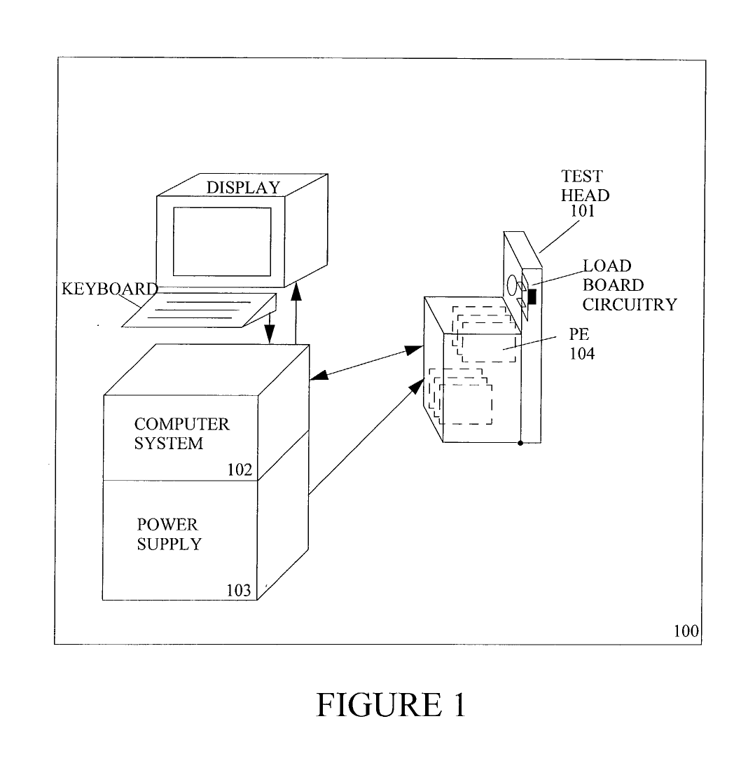

Reference is now made to FIG. 1 illustrating a high-level diagram of exemplary computer controlled Automatic Test Equipment (ATE) 100 that implements the present invention. ATE 100 comprises remote test head 101, computer system 102, and system power supplies 103. Computer system 102 is the system controller. Computer system 102 controls remote test head 101 which is electrically linked to computer system 102 by an electrical cable. Computer system 102 also acts as a hub to transfer data to/from ATE 100. Hence, computer system 102 may generally include a central processing unit (CPU), input/output (I/O) interfaces such as parallel and serial ports, communications interface for networking and communicating with the outside world, video/graphics controller, a number of data storage devices such as Read Only Memory (ROM), Random Access Memory (RAM), hard drive, and tape drive for locally storing instructions and data, I/O devices such as keyboard and video monitor to allow the operator to interact with ATE 100. It is to be appreciated that computer system 102 can be any one of a number of different computer systems including desk-top computer systems, general purpose computer systems, embedded computer systems, and others. Remote test head 101 carries all the instrument circuitry cards required to generate forced test signals and to monitor responded signals from the DUT before sending them to computer system 102 for analysis. Accordingly, remote test head 101 is used to interface with the DUT.

Remote test head 101 includes Pin Electronics (PE) circuitry 104 which provides the interface between the ATE and the DUT. More particularly, PE circuitry 104 supplies input signals to the DUT and receives output signals from the DUT. As an example, in parametric testing, either an input voltage is sent to the DUT and an output current is received from the DUT or an input current is sent to the DUT and an output voltage is received from the DUT. System power supplies 103 provide steady and uninterrupted direct current (DC) power to test head 101. Depending on its test purposes, it is to be appreciated that an ATE may have more or fewer than the components discussed above. Further, it should be clear that the components of the ATE discussed above are conventional and well known by people of ordinary skill in the art.

In one embodiment, the current measurement circuit using diodes under the present invention is implemented as part of PE circuitry 104 inside remote test head 101 to measure the current output by the DUT. In general, the I-V characteristic of a pn junction diode may be represented as:

I=Iₛ(exp{qV/kT}−1) (1)

where q is the electronic charge, k is Boltzman's constant, T is the temperature, and Iₛ depends on the constructional parameters of the diode (such as doping and area) and temperature.

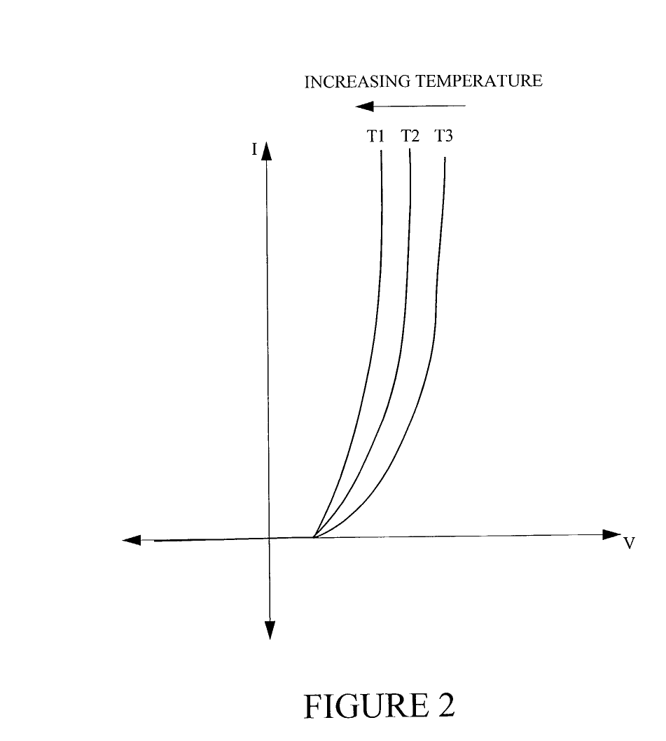

As indicated by equation (1) above, the current I across a pn junction diode is an exponential function of the voltage V applied to the diode. In other words, the applied voltage V is related to the natural logarithm of the current I. Such logarithmic relation allows a diode to accommodate a wide range of currents (i.e., over logarithmic decades). Accordingly, by using diodes to measure currents, a wide range of currents can be accommodated without switching between different resistors thereby decreasing measurement time. In addition, based on the I-V characteristic equation (1) above, the I-V characteristics of a pn junction diode are sensitive to temperature changes. FIG. 2 illustrates exemplary I-V curves of a typical pn junction diode at different temperatures T1-T3. As shown in FIG. 2, temperature changes cause the diode's I-V characteristic curve to shift. Accordingly, effects caused by temperature changes must be taken into account if diodes are to be implemented in a current measurement circuit. Self-heating of the circuit itself causes the sharpest temperature changes and is therefore a bigger concern than the effects caused by ambient temperature changes which are much more gradual. Periodic calibrations occurring at the appropriate frequency should allow for drifts caused by ambient temperature changes as well as effects due to sharp temperature changes caused, for example, by circuit self-heating to be properly accounted. In accordance with the present invention, data points of the I-V curves of the pn junction diode empirically taken as a result of the most recent calibration session are stored in memory (e.g., a data storage device), for example, in look-up tables. In accordance to the present invention, the calibration sessions are carried out frequently enough so that effects due to temperature changes (if any) are accounted for in the I-V data points empirically gathered in the last calibration session. In one embodiment, the calibration schedule may be automatically adjusted (e.g., increasing the frequency) if data points acquired in the calibration processes indicate that an adjustment of calibration frequency is necessary. For example, the frequency of of the calibration sessions may be increased if it is determined that the change between two current values I measured in response to the same input voltage Vin and using the same resistor 305 is greater than a predetermined threshold level which may indicate that effects due to temperature changes are increasing. Such determination may be carried out by computer system 102 executing some instruction steps stored in one of its storage devices (e.g., ROM) For ATEs, the speed of current measurements affored by the diode-based current measurement circuit in accordance to the present invention allows the required calibration frequency to occur so that the production testing process is not slowed down. For ATEs, the calibration process can be conveniently carried out in the period between the completion of testing of one part and the installation of the next part for testing.

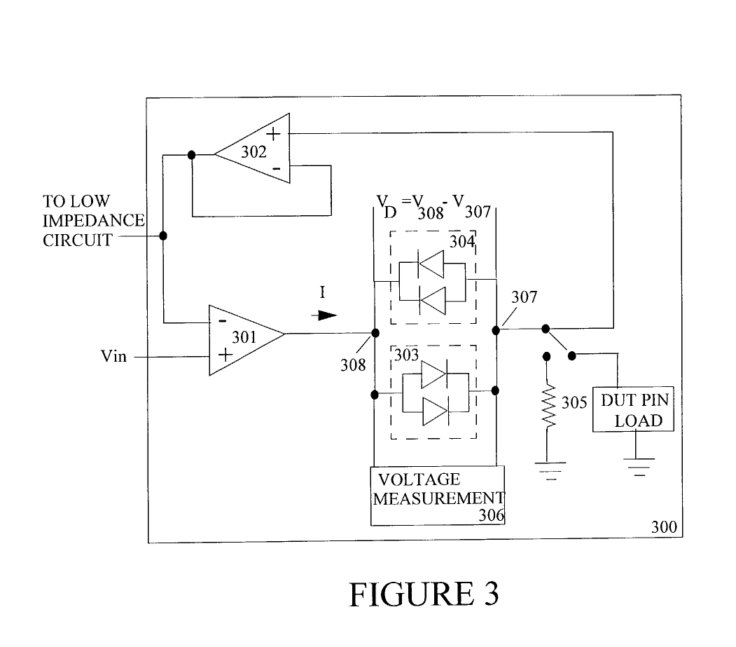

In the calibration process of the present invention, the current data points are measured by measuring a diode voltage V_{D}, which is developed as a result of a predetermined input voltage (a.k.a forced voltage) Vin applied to the current measurement circuit 300, across a precisely known resistor (e.g., resistor 305 of FIG. 3) at the output of diodes and subsequently calculating the current associated with the input voltage Vin through the diodes as the ratio of measured resistor voltage to the precisely known resistance of the resistor. The division operation is carried out by processor 102 executing instruction steps, stored in a data storage device (e.g., ROM). using the values of V_{D} and the known resistance of the resistor. The measured diode voltage V_{D} and its associated computed current I are then stored as a data point. The values of the predetermined input voltage Vin and the resistance of the precisely known resistor may be varried during the calibration process to obtain different I-V data points. In one embodiment, a look-up table is used to store all the I-V curve data points of the diode. Table 1 illustrates an example of a partial look-up table for the I-V curve data points.

TABLE 1

| Measured Diode | |
|---|---|
| Voltage (V_{D}) | Current (mA) |
| .xx | .yy |
| .zz | .ww |

For ATEs, the calibration process may be performed during a slow period when the ATE is not in use. Using the stored I-V characteristic data, a current can be determined by searching Le looked-up table or a database if a measured diode voltage V_{D} is known. The process of interpolation can be used if a measured diode voltage V_{D} falls between two stored values. Because the stored values are updated through calibration frequently enough, effects caused by the sharp temperature changes which are induced, for example by circuit self-heating, are automatically accounted. Since determining a current I involves looking up the stored value and performing an interpolation (if necessary), no resistor switching and associated settling time is required which tends to speed up the measuring process.

In one embodiment of the present invention, the effects caused by self-heating are further alleviated by the use of multiple diodes connected in parallel. Parallel diodes, whose messes are carefully chosen, reduces self-heating because the current is divided into multiple and therefore smaller currents resulting in lowered self-heating effects. Other diode arrangements (e.g., combinations of diodes in parallel and in series) are also within the scope of the present invention. Reference is now made to FIG. 3 illustrating an embodiment of current measurement circuit 300 in accordance with the present invention. As shown in FIG. 3, current measurement circuit 300 comprises first operational amplifier (op-amp) 301, second op-amp 302, first diode set 303, second diode set 304, resistor 305, and voltage measurement circuit 306. Predetermined input voltage (a.k.a. forced voltage) Vin is applied to the non-inverting input of op-amp 301. It is the current associated with predetermined input voltage Vin that current measurement circuit 300 is designed to measure. The output of op-amp 301 is connected to first diode set 303 and second diode set 304. First diode set 303 together with second diode set 304 are referred to as a diode cluster circuit. In one embodiment, first diode set 303 and second diode set 304 each includes a set of diodes connected in parallel. While FIG. 3 only shows two (2) parallel diodes in each diode set 303 and 304, it is to be appreciated that each diode set may have any number of parallel diodes.

First diode set 303 and second diode set 304 are connected in a loop (feedback) fashion. More particularly, the output of first diode set 303 is connected to the input of second diode set 304 and the input of first diode set 303 is connected to the output of second diode set 304 to allow for bi-directional current flow. This bi-directional current flow allows current measurement circuit 300 to measure currents associated with input voltage Vin regardless of whether input voltage Vin is positive or negative. Self-heating may be reduced by increasing the masses of the diodes. In one embodiment, self-heating is reduced by implementing parallel diodes in each diode set. The parallel diodes included in each diode set cause the current flowing through each diode set to be divided into smaller currents flowing through the individual diodes in the set. Each diode experiences less self-heating with a smaller current. It is to be appreciated that self-heating reduction can also be achieved by having diode sets such that each diode set has diodes connected in series. Self-heating reduction can also be achieved by having diode sets such that the diode sets alternately have diodes connected in series and diodes connected in parallel. In one embodiment, voltage measurement circuit 306 is optionnally connected between nodes 307 and 308 to monitor/measure the voltage drop between nodes 307 and 308 which is referred to as measured diode voltage V_{D}. Measured diode voltage V_{D}, which is generated in response to predetermined input voltage Vin, is then provided to computer system 102 for processing. Alternatively, computer system 102 reads voltage measurements at nodes 307 and 308 and performs the necessary calculations to determine measured diode voltage V_{D}.

First diode set 303 and second diode set 304 are in turn connected to one end of resistor 305 via switch 309 and to the non-inverting input of second op-amp 302. The other end of resistor 305 is connected to ground. It is to be appreciated that resistor 305, whose value is predetermined and very precise, is used only during the calibration process. For actual production measurements, the DUT pin load replaces resistor 305. Hence, switch 309 may be optionally implemented to switch between resistor 305 in the calibration mode or the DUT pin load in the production measurement mode. The output of second op-amp 302 is connected to its inverting input as well as to the inverting input of op-amp 301. The inverting input of op-amp 301 is connected to a low input impedance circuit which is not shown here because it is beyond the scope of the present invention. In short, op-amps 301 and 302 with their feedback loops and configurations act as voltage followers. As is consistent with the characteristics of a voltage follower, the voltage follower made up of op-amp 301 acts to ensure that the voltage at node 307 is equal to input voltage Vin despite the voltage drop across diode sets 303 and 304. On the other hand, the voltage follower made up of op-amp 302 serves as a high impedance buffer to prevent an excess current from being drawn into the non-inverting input of op-amp 301 when a low impedance circuit is connected thereto. Such a high impedance buffer may be needed in the presence of the low impedance circuit to prevent a distorted and therefore incorrect current reading associated with input voltage Vin. As such, the voltage follower made up of op-amp 302 is included here as an option to counter such a problem and may not be required under other circumstances under other circumstances.

Operationally, when an input voltage Vin is provided to the non-inverting input of op-amp 301 either during the production measurement mode or the calibration mode, a substantially equivalent voltage is output by op-amp 301 to the inputs of diode sets 303-304 (node 308). If the output of op-amp 301 is a positive voltage, diode set 303 outputs a current based on equation (1) above across resistor 305 or the DUT pin load depending on the application. On the other hand, if the output of op-amp 301 is negative voltage, diode set 304 outputs a current with a substantially equivalent magnitude to the current output by diode set 303 but in an opposite direction. Current measurement circuit 300 together with executed instructions and tabulated calibration data, stored in at least one data storage device (e.g., ROM and disk drive), is designed to measure the current output by either diode set 303 or 304 (i.e., the current associated with input voltage Vin). In short, during both the production measurement mode and the calibration mode, the current output is determined by using measured diode voltage VD (measured by voltage measurement circuit 306 or determined by computer system 102) as an index to look up the associated current in the database which is, in one embodiment, a lookup table.

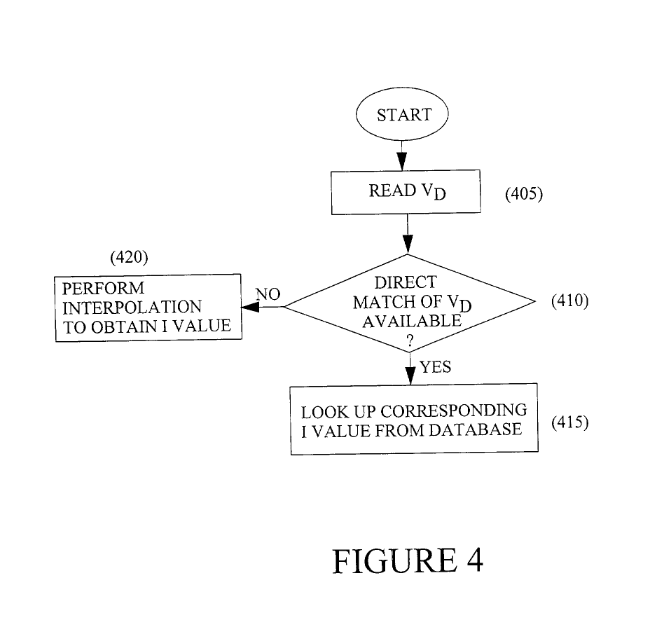

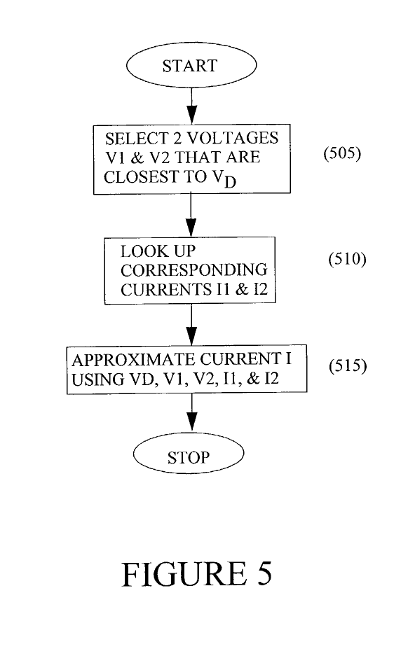

Reference is now made to FIG. 4 illustrating an exemplary flow chart of the instructions stored in a data storage device of computer system 102 which when executed by the CPU determines the current associated with input voltage Vin. When input voltage Vin is applied to current measurement circuit 300, the CPU determines the diode voltage V_{D} (step 405). Such determination may be made, for example, by reading the output of voltage measurement circuit 306 which measures the voltage gradient between nodes 307 and 308. Alternatively, such determination may be made by separately reading the voltages at nodes 307-308 and then computing the difference between the voltage readings. Using the measured diode voltage V_{D} as an index, the CPU determines whether there is a voltage data point stored in the database that matches the measured diode voltage VD (step 410). If there is such a match, the CPU looks up the current I value that corresponds to the measured diode voltage V_{D} in the database (step 415). Otherwise, if there is no such match, the CPU carries out the interpolation steps which are discussed in greater detail below in association with FIG. 5 (step 420).

FIG. 5 illustrates, as an example, a flow chart of the interpolation steps associated with step 420 of FIG. 4. To summarize, in step 420, the measured diode voltage V_{D} does not match with any available voltage data points in the table. Accordingly, the CPU selects from the available voltage data points two voltages V1 and V2 closest in value VD and that input voltage Vin falls between (step 505). To improve the interpolation accuracy, V1 and V2 should be the two voltage data points that are immediately adjacent (closest in value) to V_{D}. Next in step 510, using voltage values V1 and V2 as indices, the CPU look up the corresponding current values I1 and I2 in the database. The CPU can then compute the current I associated with input voltage Vin by using any one of many interpolation equations. An example of an interpolation equation that can be used is:

I=I1+{(Vin−V1)/(V2−V1)}*(I2−I1) (2)

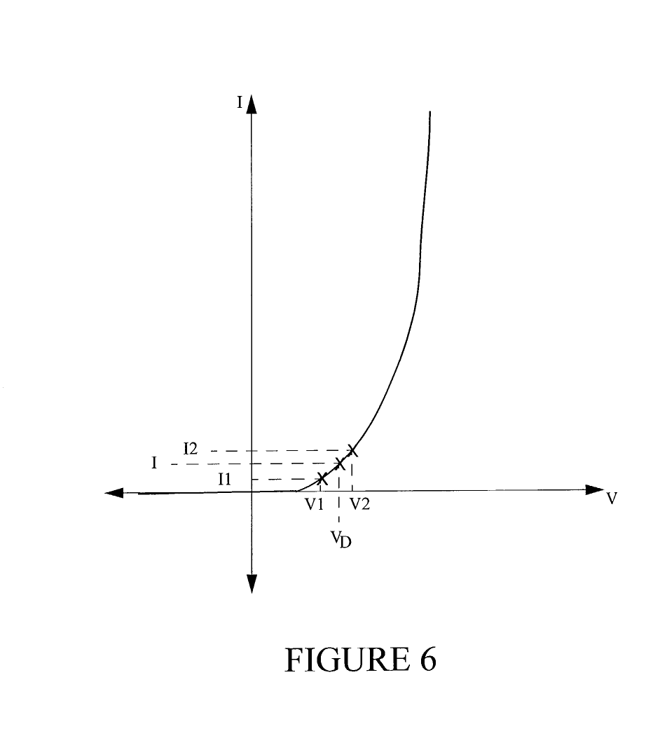

It should be clear to a person of ordinary skill in the art that equation (2) can easily be derived by observing the geometrical relationship between the different parameters: I1, I2, Vin, V1, and V2. This geometrical relationship is illustrated, as an example, in FIG. 6. While the interpolation process associated with equation (2) is a linear one (i.e., related to a straight line approximation), it is clear that other linear and non-linear interpolation processes such as logarithmic can also be used and is within the scope of the present invention.

An embodiment of the present invention, an ATE current measurement methodology and apparatus that minimize the overall current measurement time over a wide dynamic current range while still achieving the required sensitivities, accuracies, and resolutions, is thus described. While the present invention has been described in a particular embodiment, the present invention should not be construed as limited by such an embodiment, but rather construed according to the below claims.

What is claimed is:

1. An ATE system comprising:
a central processing unit (CPU);
at least one data storage device coupled to the CPU; and
a test head electrically linked to the CPU, the test head including a pin electronics (PE) circuit for interfacing with a Device Under Test (DUT), the PE circuit having a current measurement circuit comprising:
a first voltage follower circuit having an inverted input, a non-inverted input, and an output, the first voltage follower circuit receiving a predetermined voltage at a non-inverted input; and
a diode cluster circuit having an input and an output, the input of the diode cluster circuit connected to the output of the first voltage follower circuit, the output of the diode cluster circuit coupled to the non-inverted input of the first voltage follower, the diode cluster circuit providing a current at the output;
wherein the data storage device storing current-voltage (I-V) characteristics data points measured across the diode cluster circuit, the data storage device further storing instructions which when executed by the CPU performs the following steps: determining the voltage across the diode cluster circuit, using the voltage across the diode cluster circuit as an index determining a corresponding current value from the stored I-V characteristics data points, and outputting the corresponding current value as a measured current.

2. The ATE system of claim 1, wherein the I-V characteristics data points stored in the data storage device are updated periodically by calibration sessions performed at a frequency such that any effects due to temperature changes are accounted for in the stored I-V data points.

3. The ATE system of claim 2, wherein the calibration frequency is varried to counter increasing effects due to temperature changes.

4. The ATE system of claim 3 further comprising a resistor connected to the output of the diode cluster circuit for use during calibration sessions, wherein a value of the predetermined voltage and a value of the resistor are varied to generate different I-V characteristics data points during calibration sessions.

5. The ATE system of claim 4, wherein during calibration sessions, the CPU executes additional instructions to compute he current output by the diode cluster circuit by dividing the voltage taken across the diode cluster circuit by a resistance value of the resistor.

6. The ATE system of claim 2, wherein the determining the corresponding current value step involves looking up the corresponding current value stored in the data storage device using the voltage measured across the diode cluster diode as an index, if there is a match between the index and a stored voltage data point, outputting a stored current value data point corresponding to the stored voltage data as a measured current, if there is no match, performing an interpolation process to compute an interpolated current value, and outputting the interpolated current value as the measured current.

7. The ATE system of claim 2, wherein the current measurement circuit further comprises a second voltage follower circuit coupled between the output of the diode cluster circuit and the inverted input of the first voltage follower circuit, the second voltage follower circuit preventing excessive current from being drawn thereby preventing significant measurement error.

8. The ATE system of claim 2, wherein the diode cluster circuit comprising:
a first diode set having a plurality of pn junction diodes connected together in parallel, the first diode set having an input and an output; and
a second diode set having a plurality of pn junction diodes connected together in parallel, the second diode set having an input and an output wherein the input of the first diode set is connected to the output of the second diode set and the output of the first diode set is connected to the input of the second diode set.

9. The ATE system of claim 2, wherein the interpolation process involves interpolating using two voltage data points that are closest in value to the voltage taken across the diode cluster diode.

10. A current measuring apparatus comprising:
a first voltage follower circuit having an inverted input, a non-inverted input, and an output, the first voltage follower circuit receiving a predetermined voltage at a non-inverted input;
a diode cluster circuit having an input and an output, the input of the diode cluster circuit connected to the output of the first voltage follower circuit, the output of the diode cluster circuit coupled to the non-inverted input of the first voltage follower, the diode cluster circuit providing a current at the output;
a processor coupled to the diode cluster circuit; and
at least one data storage device coupled to the processor, the data storage device storing current-voltage (I-V) characteristics data points measured across the diode cluster circuit, the data storage device further storing instructions which when executed by the processor performs the following steps: determining the voltage across the diode cluster circuit, using the voltage across the diode cluster circuit as an index determining a corresponding current value from the stored I-V characteristics data points, and outputting the corresponding current value as a measured current.

11. The current measurement apparatus of claim 10, wherein the I-V characteristics data points stored in the data storage device are updated periodically by calibration sessions performed at a frequency such that any effects due to temperature changes are accounted for in the stored I-V data points.

12. The current measurement apparatus of claim 11, wherein the calibration frequency is varried to counter increasing effects due to temperature changes.

13. The current measurement apparatus of claim 12 further comprising a resistor connected to the output of the diode cluster circuit for use during calibration sessions, wherein a value of the predetermined voltage and a value of the resistor are varied to generate different I-V characteristics data points during calibration sessions.

14. The current measurement apparatus of claim 13, wherein during calibration sessions, the CPU executes additional instructions to compute the current output by the diode cluster circuit by dividing the voltage measured across the diode cluster circuit by a resistance value of the resistor.

15. The current measurement apparatus of claim 11, wherein the determining the corresponding current value step involves looking up the corresponding current value stored in the data storage device using the voltage measured across the diode cluster diode as an index, if there is a match between the index and a stored voltage data point, outputting a stored current value data point corresponding to the stored voltage data as a measured current, if there is no match, performing an interpolation process to compute an interpolated current value, and outputting the interpolated current value as the measured current.

16. The current measurement apparatus of claim 11, wherein the current measurement circuit further comprises a second voltage follower circuit coupled between the output of the diode cluster circuit and the inverted input of the first voltage follower circuit, the second voltage follower circuit preventing excessive current from being drawn.

17. The current measurement apparatus of claim 11, wherein the diode cluster circuit comprising:
a first diode set having a plurality of pn junction diodes connected together in parallel, the first diode set having an input and an output; and
a second diode set having a plurality of pn junction diodes connected together in parallel, the second diode set having an input and an output wherein the input of the first diode set is connected to the output of the second diode set and the output of the first diode set is connected to the input of the second diode set.

18. The current measurement apparatus of claim 11, wherein the interpolation process involves interpolating using two voltage data points that are closest in value to the voltage measured across the diode cluster diode.

19. A method to measure a current of an input voltage comprising:
storing current-voltage (I-V) characteristics data points measured at a diode circuit during calibration sessions, wherein the I-V characteristics data points stored in the data storage device are updated periodically by calibration sessions performed at a frequency such that any effects due to temperature changes are accounted for in the stored I-V data points;
using the voltage across the diode cluster circuit as an index, determining a corresponding current value from the stored I-V characteristics data points; and
outputting the corresponding current value as a measured current.

20. The current measuring method of claim 19, wherein the calibration frequency is varried to counter increasing effects due to temperature changes.

21. The current measuring method of claim 15, wherein the determining the corresponding current value step involves:
looking up a corresponding current value stored using the voltage measured across the diode cluster diode as an index;
if there is a match between the index and a stored voltage data point, outputting a stored current value data point corresponding to the stored voltage data as a measured current; and
if there is no match, performing an interpolation process to compute an interpolated current value, and outputting the interpolated current value as the measured current.

22. The current measuring method of claim 21, wherein the interpolation process involves interpolating using two voltage data points that are closest in value to the voltage measured across the diode cluster diode.
